(19) United States
(12) Patent Application Publication
(10) Pub. No.: US 2026/0033298 A1
(43) Pub. Date: Jan. 29, 2026

(54) SELECTIVE PHOTO-RESIST RE-SHAPING

(71) Applicant: Applied Materials, Inc., Santa Clara, CA (US)

(72) Inventors: Zeqing Shen, San Jose, CA (US); Sai Hooi Yeong, Cupertino, CA (US); Kashish Sharma, Santa Clara, CA (US); Abhijit Basu Mallick, Sunnyvale, CA (US); Balasubramanian Pranatharthiharan, San Jose, CA (US)

(73) Assignee: Applied Materials, Inc., Santa Clara, CA (US)

(21) Appl. No.: 19/272,350

(22) Filed: Jul. 17, 2025

Related U.S. Application Data
(60) Provisional application No. 63/675,051, filed on Jul. 24, 2024.

(51) Int. Cl. H01L 21/033; H01L 21/311

(52) U.S. Cl. CPC H01L 21/0337; H01L 21/31144

(57) ABSTRACT

Methods and systems for semiconductor processing are provided. Methods and systems include forming a selective layer of carbon-containing material on a photoresist material disposed over a surface of a substrate within a processing region of a semiconductor processing chamber. Methods and systems include where the layer of carbon-containing material is selectively formed over the photoresist material. Methods and systems include forming the layer of carbon-containing material by using one or more cycles of: providing a first molecular species that selectively couples with the photoresist material, and providing a second molecular species that selectively couples with the first molecular species.

### CROSS-REFERENCE TO RELATED APPLICATIONS

This application claims benefit of U.S. Provisional Patent Application No. 63/675,051, entitled “SELECTIVE PHOTO-RESIST RE-SHAPING,” filed Jul. 24, 2024, the contents of which are hereby incorporated by reference in their entirety.

### TECHNICAL FIELD

The present technology relates to systems and methods for semiconductor processing. More specifically, the present technology relates to systems and methods for selectively forming molecular layers on semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, and device complexity continues to increase, producing structures has become increasingly complex. Developing structures may take many more operations to produce the complex patterning and material integration. Additionally, as devices to continue to reduce in size, the patterning materials must be able to be deposited at controlled dimensions to allow for the necessary patterning procedures.

Thus, there is a need for improved systems and methods that can be used to produce high quality devices and structures. These and other needs are addressed by the present technology.

### SUMMARY

The present technology is generally directed to semiconductor processing methods. Methods include forming a selective layer of carbon-containing material on a photoresist material disposed over a surface of a substrate within a processing region of a semiconductor processing chamber. Methods include where the selective layer of carbon-containing material is formed over at least one or more sidewalls of the photoresist material. Methods include where forming the selective layer of carbon-containing material includes one or more cycles of providing a first molecular species that selectively couples with the photoresist material and providing a second molecular species that selectively couples with the first molecular species.

In embodiments, the selective layer of carbon-containing material is formed over the one or more sidewalls and one or more top surfaces of the photoresist material. Moreover, in embodiments, methods include forming a helmet or cap over the selective layer of carbon-containing material on the one or more top surfaces of the photoresist material. In further embodiments, the helmet or cap includes a carbon-containing material. Additionally or alternatively, in embodiments, the helmet or cap is formed by molecular layer deposition, chemical vapor deposition, or a combination thereof. In embodiments, the selective layer of carbon-containing material is deposited by molecular layer deposition. Embodiments include where the selective layer of carbon-containing material is deposited at a thickness of less than or about 5 nm. In yet more embodiments, the selective layer of carbon-containing material is deposited at a thickness of less than or about 4 nm over the one or more sidewalls and the one or more top surfaces of the photoresist material. Furthermore, in embodiments, the helmet or cap is formed at a thickness of greater than or about 5 nm. In embodiments, the helmet or cap increases a height of the photoresist material. Moreover, in embodiments, the selective layer of carbon-containing material decreases a critical dimension between adjacent features of the photoresist material. In embodiments, the selective layer of carbon-containing material is formed at a temperature of less than or about 150° C.

The present technology is also generally directed to semiconductor processing methods. Methods include flowing a first deposition precursor into a substrate processing region, contacting a photoresist material formed over a surface of a substrate within the processing region of a semiconductor processing chamber, selectively forming a first portion of a carbon-containing material. Methods include flowing a second deposition precursor into the substrate processing region, contacting the first portion of the carbon-containing material, forming a second portion of the carbon-containing material. Methods include where the carbon-containing material is selectively formed over the photoresist material.

In embodiments, the carbon-containing material is selective formed over one or more sidewalls and one or more top surfaces of the photoresist material. Furthermore, in embodiments, methods include forming a helmet or cap over the selective carbon-containing material on the one or more top surfaces of the photoresist material. In more embodiments, the helmet or cap includes a carbon-containing material and the helmet or cap is formed by molecular layer deposition, chemical vapor deposition, or a combination thereof, selectively over the selective carbon-containing material on the one or more top surfaces of the photoresist material. Additionally or alternatively, in embodiments, the selective carbon-containing material is deposited at a thickness of less than or about 4 nm over the one or more sidewalls and the one or more top surfaces of the photoresist material and the helmet or cap is formed at a thickness of greater than or about 5 nm.

The present technology is also generally directed to semiconductor processing methods. Methods include forming a selective layer of carbon-containing material on a photoresist material formed over a dielectric material disposed on a surface of a substrate within a processing region of a semiconductor processing chamber at a processing region temperature of less than or about 100° C. Methods include where the selective layer of carbon-containing material is selectively formed over the photoresist material. Methods include where forming the selective layer of carbon-containing material includes one or more cycles of providing a first molecular species that selectively couples with photoresist material and providing a second molecular species that selectively couples with the first molecular species. In embodiments, methods include forming a helmet or cap over the selective layer of carbon-containing material on one or more top surfaces of the photoresist material. Furthermore, embodiments include etching an exposed portion of the dielectric material after forming the selective layer of carbon-containing material.

Such technology may provide numerous benefits over conventional systems and techniques. For example, embodiments of the present technology may produce selectively deposited photo-resist materials on tailored surfaces of an as-deposited photoresist pattern, which may allow subsequent carefully controlled etch of exposed materials. Additionally, the present technology may produce photoresist patterns that can be formed on a desired lateral or vertical surface, or both vertical and lateral surfaces of an as-deposited photo resist pattern, even at tailored thicknesses. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top-down view of an exemplary plasma system according to embodiments of the present technology.

FIG. 2 shows a schematic cross-sectional view of an exemplary plasma system according to embodiments of the present technology.

FIG. 3 shows operations in a semiconductor processing method according to embodiments of the present technology.

FIGS. 4A-4D show exemplary schematic cross-sectional structures according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

When moving towards smaller technology nodes, such as the 7 nm node and smaller in semiconductor fabrication, improved techniques for patterning, such as extreme ultraviolet (“EUV”) lithography may be used. EUV lithography utilizes a photomask structure that has been patterned with a specific integrated circuit design. The photomask is then incorporated in a lithography scanner, and used to pattern images on a substrate. EUV technology may be characterized by several challenges, including patterning small features with the photoresist material. One issue includes the imperfect patterning of the photoresist that results in openings in the photoresist, or apertures, being characterized by sidewalls having a greater critical distance between adjacent sidewalls than desired, and thus an increased critical dimension. Existing photoresist materials and deposition patterns have failed to deposit patterns suitable for continuously shrinking devices, resulting in deviations from the desired pattern. These nonuniformities may propagate through underlying layers during patterning processes and may result in wasted materials due to the pattern being unable to achieve the desired critical dimensions.

In addition, existing methods and system fail to produce photoresist patterning with sufficient height to enable etching of high aspect ratio or deep features, particularly when paired with narrow critical dimensions (e.g. high aspect ratios). For instance, conventional technologies have struggled to produce selectively deposited photoresist materials that provide sufficient protection (e.g. allow for significant etch depth) for subsequent etch operations. In embodiments, it is desirable, or even necessary to decrease a pitch, increase a height, or both, of a photoresist pattern, in order to adequately etch the desired feature. Furthermore, existing technology has so far failed to provide methods and materials that allow for correction of as-deposited photo resist patterns.

The present technology overcomes these issues by performing selective molecular layer deposition on a photoresist pattern formed over a substrate, to produce re-shaped photoresist patterns having a decreased pitch, an increased height, or both, as compared to the as-deposited photoresist pattern. Unlike conventional technologies, the presently disclosed materials and techniques may facilitate formation of re-shaped photoresist materials exhibiting an increased thickness (e.g. decreased pitch) or height as compared to the as-deposited photoresist material. In addition, the re-shaping materials may also have removal characteristic similar to, or the same as, the underlying photoresist material. Furthermore, the present materials may be capable of selectively depositing on a sidewall or a top surface of the as-deposited photoresist pattern, allowing for careful control of the re-shaped photoresist material.

Although the remaining disclosure will routinely identify specific deposition processes utilizing the disclosed technology, and will describe one type of semiconductor processing chamber, it will be readily understood that the processes described may be performed in any number of semiconductor processing chambers. Additionally, the present technology may be applicable to any number of semiconductor processes, beyond the exemplary process described below. For example, the present technology may facilitate processes including selective deposition at back end of line, self-aligned via formation, and any number of additional processes in which photoresist materials may be used to facilitate selective etching of exposed surfaces. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

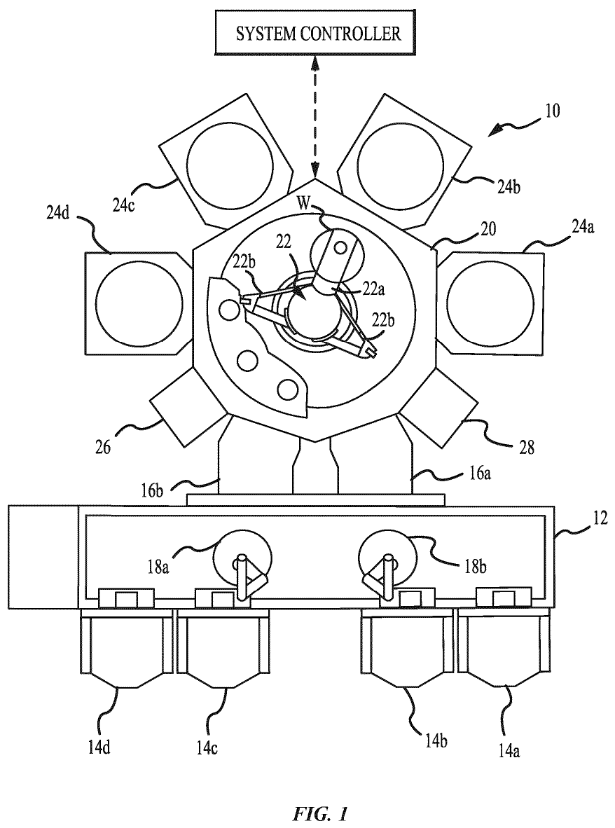

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

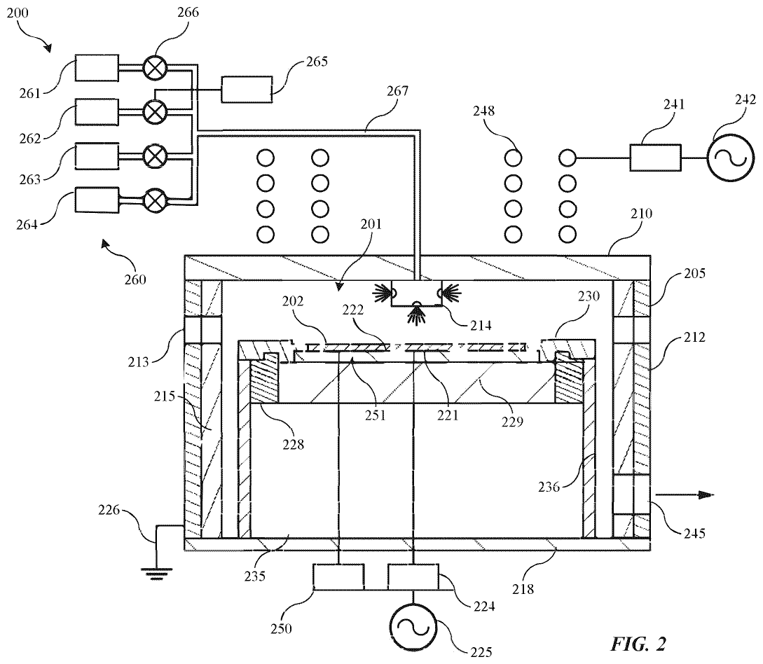

FIG. 2 illustrates a schematic cross-sectional view of an exemplary processing chamber 200 suitable for patterning a material layer disposed on a substrate 202 in the processing chamber 200. The exemplary processing chamber 200 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 200 may include a chamber body 205 defining a chamber volume 201 in which a substrate may be processed. The chamber body 205 may have sidewalls 212 and a bottom 218 which are coupled with ground 226. The sidewalls 212 may have a liner 215 to protect the sidewalls 212 and extend the time between maintenance cycles of the plasma processing chamber 200. The dimensions of the chamber body 205 and related components of the plasma processing chamber 200 are not limited and generally may be proportionally larger than the size of the substrate 202 to be processed therein. Examples of substrate sizes include 200 mm diameter, 250 mm diameter, 300 mm diameter and 450 mm diameter, among others, such as display or solar cell substrates as well.

The chamber body 205 may support a chamber lid assembly 210 to enclose the chamber volume 201. The chamber body 205 may be fabricated from aluminum or other suitable materials. A substrate access port 213 may be formed through the sidewall 212 of the chamber body 205, facilitating the transfer of the substrate 202 into and out of the plasma processing chamber 200. The access port 213 may be coupled with a transfer chamber and/or other chambers of a substrate processing system as previously described. A pumping port 245 may be formed through the sidewall 212 of the chamber body 205 and connected to the chamber volume 201. A pumping device may be coupled through the pumping port 245 to the chamber volume 201 to evacuate and control the pressure within the processing volume. The pumping device may include one or more pumps and throttle valves.

A gas panel 260 may be coupled by a gas line 267 with the chamber body 205 to supply process gases into the chamber volume 201. The gas panel 260 may include one or more process gas sources 261, 262, 263, 264 and may additionally include inert gases, non-reactive gases, and reactive gases, as may be utilized for any number of processes. Examples of process gases that may be provided by the gas panel 260 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, silicon and hydrogen containing gases such as BCl₃, Cl₂, SiCl₄, CF₄, C₂F₄, C₄F₈, C₄F₆, CHF₃, CH₂F₂, CH₃F, NF₃, NH₃, CO₂, SO₂, CO, COS, N₂, NO₂, N₂O, O₂, HBr, and H₂, among any number of additional precursors.

Valves 266 may control the flow of the process gases from the sources 261, 262, 263, 264 from the gas panel 260 and may be managed by a controller 265. The flow of the gases supplied to the chamber body 205 from the gas panel 260 may include combinations of the gases form one or more sources. The lid assembly 210 may include a nozzle 214. The nozzle 214 may be one or more ports for introducing the process gases from the sources 261, 262, 264, 263 of the gas panel 260 into the chamber volume 201. After the process gases are introduced into the plasma processing chamber 200, the gases may be energized to form plasma. An antenna 248, such as one or more inductor coils, may be provided adjacent to the plasma processing chamber 200. An antenna power supply 242 may power the antenna 248 through a match circuit 241 to inductively couple energy, such as RF energy, to the process gas to maintain a plasma formed from the process gas in the chamber volume 201 of the plasma processing chamber 200. Alternatively, or in addition to the antenna power supply 242, process electrodes below the substrate 202 and/or above the substrate 202 may be used to capacitively couple RF power to the process gases to maintain the plasma within the chamber volume 201. The operation of the power supply 242 may be controlled by a controller, such as controller 265, that also controls the operation of other components in the plasma processing chamber 200.

A substrate support pedestal 235 may be disposed in the chamber volume 201 to support the substrate 202 during processing. The substrate support pedestal 235 may include an electrostatic chuck 222 for holding the substrate 202 during processing. The electrostatic chuck (“ESC”) 222 may use the electrostatic attraction to hold the substrate 202 to the substrate support pedestal 235. The ESC 222 may be powered by an RF power supply 225 integrated with a match circuit 224. The ESC 222 may include an electrode 221 embedded within a dielectric body. The electrode 221 may be coupled with the RF power supply 225 and may provide a bias which attracts plasma ions, formed by the process gases in the chamber volume 201, to the ESC 222 and substrate 202 seated on the pedestal. The RF power supply 225 may cycle on and off, or pulse, during processing of the substrate 202. The ESC 222 may have an isolator 228 for the purpose of making the sidewall of the ESC 222 less attractive to the plasma to prolong the maintenance life cycle of the ESC 222. Additionally, the substrate support pedestal 235 may have a cathode liner 236 to protect the sidewalls of the substrate support pedestal 235 from the plasma gases and to extend the time between maintenance of the plasma processing chamber 200.

Electrode 221 may be coupled with a power source 250. The power source 250 may provide a chucking voltage of about 200 volts to about 2000 volts to the electrode 221. The power source 250 may also include a system controller for controlling the operation of the electrode 221 by directing a DC current to the electrode 221 for chucking and de-chucking the substrate 202. The ESC 222 may include heaters disposed within the pedestal and connected to a power source for heating the substrate, while a cooling base 229 supporting the ESC 222 may include conduits for circulating a heat transfer fluid to maintain a temperature of the ESC 222 and substrate 202 disposed thereon. The ESC 222 may be configured to perform in the temperature range required by the thermal budget of the device being fabricated on the substrate 202. For example, the ESC 222 may be configured to maintain the substrate 202 at a temperature of about −150° C. or lower to about 500° C. or higher depending on the process being performed.

The cooling base 229 may be provided to assist in controlling the temperature of the substrate 202. To mitigate process drift and time, the temperature of the substrate 202 may be maintained substantially constant by the cooling base 229 throughout the time the substrate 202 is in the chamber. In some embodiments, the temperature of the substrate 202 may be maintained throughout subsequent processes at temperatures between about −150° C. and about 500° C., although any temperatures may be utilized. A cover ring 230 may be disposed on the ESC 222 and along the periphery of the substrate support pedestal 235. The cover ring 230 may be configured to confine etching gases to a desired portion of the exposed top surface of the substrate 202, while shielding the top surface of the substrate support pedestal 235 from the plasma environment inside the plasma processing chamber 200. Lift pins may be selectively translated through the substrate support pedestal 235 to lift the substrate 202 above the substrate support pedestal 235 to facilitate access to the substrate 202 by a transfer robot or other suitable transfer mechanism as previously described.

The controller 265 may be utilized to control the process sequence, regulating the gas flows from the gas panel 260 into the plasma processing chamber 200, and other process parameters. Software routines, when executed by the CPU, transform the CPU into a specific purpose computer such as a controller, which may control the plasma processing chamber 200 such that the processes are performed in accordance with the present disclosure. The software routines may also be stored and/or executed by a second controller that may be associated with the plasma processing chamber 200.

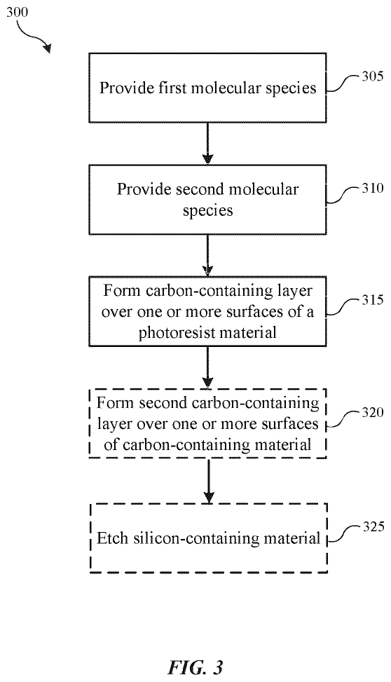

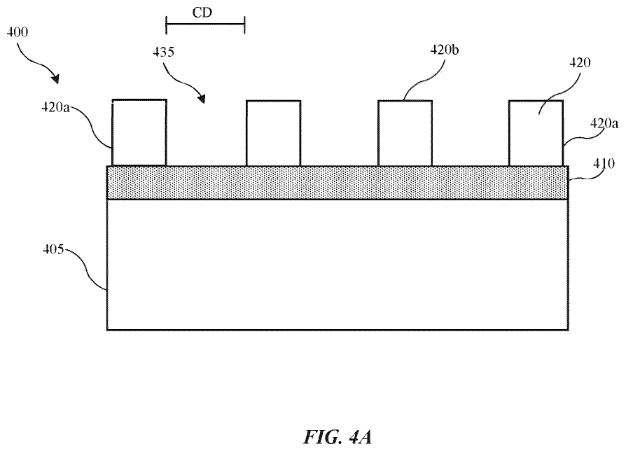

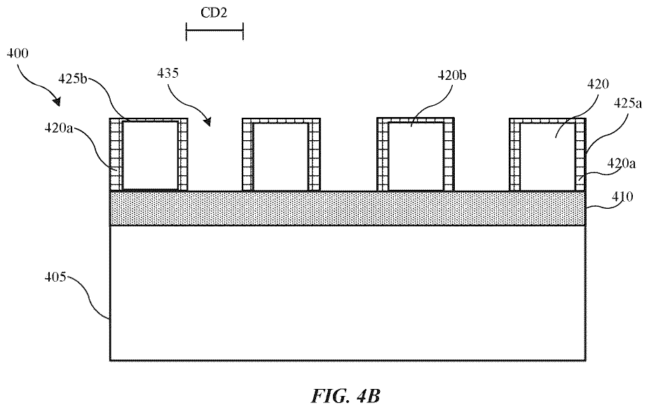

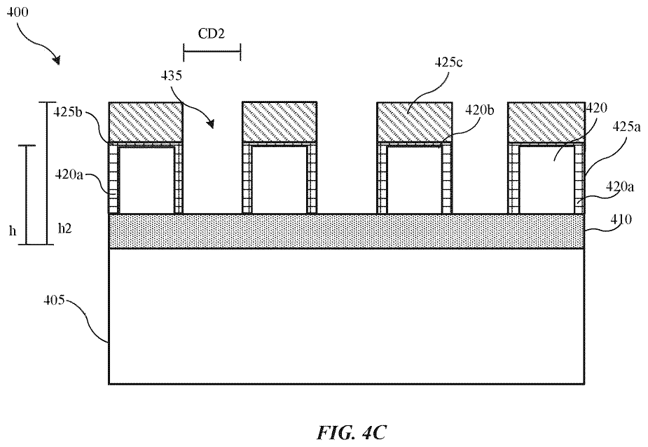

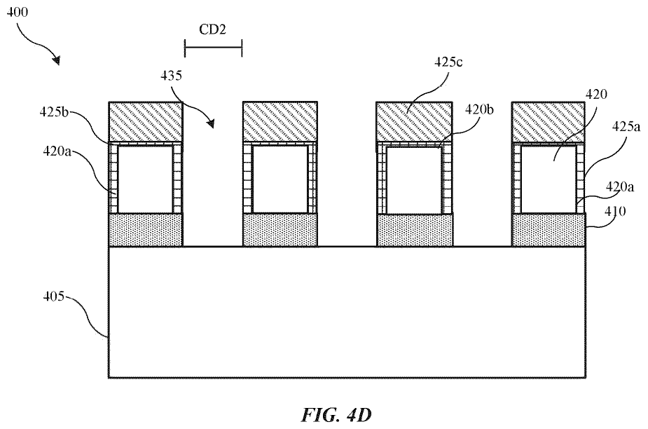

Although a plasma-processing chamber may be used for one or more aspects of film processing, in some embodiments forming molecular layer deposition films may not utilize a plasma-enhanced process for some or all of the operations, although the processes may partially or fully be performed in chambers in which plasma may be formable for subsequent deposition. The present technology may at least form one or more layers over an existing photoresist pattern without plasma generation, in some embodiments. FIG. 3 shows exemplary operations in a processing method 300 according to some embodiments of the present technology. The method may be performed in a variety of processing chambers, including processing chamber 100 and/or 200 described above, as well as any other chambers in which the operations may be performed. Method 300 may include one or more operations prior to the initiation of the method, including front-end processing, deposition, etching, polishing, cleaning, or any other operations that may be performed prior to the described operations. The methods may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4D, the illustrations of which will be described in conjunction with the operations of method 300. It is to be understood that the figures illustrate only partial schematic views, and a substrate may contain any number of additional materials and features having a variety of characteristics and aspects as illustrated in the figures. Additionally, it is to be understood that the figures illustrate just one exemplary process in which molecular layer deposition according to embodiments of the present technology may be employed, and the description is not intended to limit the technology to this process alone.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which a selective deposition material may be formed. As illustrated in FIG. 4A substrate 405 may be processed to a position in which multiple materials may be exposed along a surface of the substrate. Substrate 405 may be any number of materials, such as a base wafer or substrate made of silicon or silicon-containing materials, germanium, other substrate materials, as well as one or more materials that may be formed overlying the substrate during semiconductor processing.

For example, in some embodiments the substrate may be processed to include one or more materials or structures for semiconductor processing. Substrate 405 may also include one or more layers of a dielectric material 410, overlying some or all of the substrate 405. In embodiments, dielectric material 410 may include an oxide or nitride of any number of materials. For instance, in embodiments, the dielectric material 410 may include an oxide or nitride of silicon, and be one or more silicon-containing materials. In embodiments, silicon-containing materials may include a silicon-and-oxygen-containing material, a silicon-and-nitrogen-containing material, silicon-and-oxygen-and-nitrogen-containing material, or any other silicon-containing material.

As illustrated, in embodiments, the semiconductor structure 400 may also include a photoresist material 420. The photoresist material 420 may be patterned to define at least one aperture 435 extending through an entire thickness of the photoresist material 420. The aperture 435 may expose the underlying dielectric material 410. Although the semiconductor structure 400 is illustrated with only three apertures 435, exemplary structures 400 may include any number of apertures previously discussed, which can include dozens or hundreds of apertures, and it is to be understood that the figures are only schematics to illustrate aspects of the present technology. The apertures 435 may have a width of less than or about 30 nm, such less than or about 28 nm, less than or about 26 nm, less than or about 24 nm, less than or about 22 nm, less than or about 20 nm, less than or about 18 nm, less than or about 16 nm, less than or about 14 nm, less than or about 12 nm, less than or about 10 nm, or less.

However, as discussed above, existing photoresist materials lack the capability to consistently form apertures having small widths, and completely fail to form apertures having limited widths and/or high aspect ratios. This is problematic as, such deficiencies in existing photoresist materials lead to the formation of larger vias or trenches than planned or desired. Additionally or alternatively, if the photoresist material has an insufficient height, due to aspect ratio limitations during pattern formation, the photoresist material may be completely consumed prior to etching the full depth of the desired feature. This is also problematic as it may result in uneven etching, forming features with uneven widths along the depth of the feature.

Thus, method 300 according to the present technology may include selectively forming a carbon-containing material on the photoresist material 420 by performing a molecular layer deposition process. Unlike atomic layer deposition, which is limited to deposition of large amounts of material and which fails to form on a consistent layer-by-layer basis, the present technology may provide tailored coverage or targeted thicknesses, even at small deposition thicknesses, which allows for the carefully controlled re-shaping of photoresist material 420. Moreover, the molecular layer deposition processes discussed herein may also allow for one or more layers of the carbon containing material to be deposited over the photoresist material 420 with a high degree of selectivity. Thus, the present technology may allow for formation of re-shaping materials on one or more sidewalls 420a of the photoresist material 420, on a top surface 420b of the photoresist material 420, or both. Furthermore, the material may selectively form only over the photoresist material 420, such that little to not material is formed over dielectric material 410. In addition, the processes and methods discussed herein may provide for the deposition of materials having similar etch properties to the photoresist material 420, allowing for selectivity to be maintained during both feature etch and removal of the photoresist material 420.

Forming the photoresist re-shaping material 425, which may include one or more layers, may include a sequential process of molecular layer deposition. For example, a first molecular species may be provided to the substrate at operation 305. The first molecular species may couple with or otherwise bond to exposed surfaces of photoresist material 420. The first molecular species may not effectively couple, or may have reduced coupling, with the exposed dielectric material, such as silicon oxide or silicon nitride, among any number of other dielectric materials. After sufficient exposure to the first molecular species, a purge operation may be performed. At operation 210, a second molecular species may be provided, and which may selectively couple with the first molecular species.

In embodiments, the first molecular species may include a head group that adsorbs or otherwise couples with one or more exposed surfaces of the photoresist material 420, and which may produce a first molecular layer overlying the photoresist material. The second molecular species may couple specifically with the first molecular species, allowing a second molecular layer to form overlying the first molecular layer, forming the re-shaping material 425. The process then may be repeated for any number of cycles to produce the desired thickness to the re-shaping material, forming a carbon-containing material at operation 315. For example, after the second molecular species is purged, the first molecular species may be provided again, which may couple with the second molecular species and form another first molecular layer. The processing region may then be purged, and the second molecular species may be provided to form another second molecular layer. Although only four layers are discussed for forming at least a first portion (e.g. all or some of portions 425a and 425b) of the re-shaping material 425, it is to be understood that any number of cycles may be performed, which may include dozens of layers in some embodiments, forming re-shaping material 425.

The formation of the carbon-containing layer may utilize molecular deposition species characterized by materials facilitating long chain production, and which may selectively couple with the one or more of the sidewalls or top surface of the photoresist material when utilizing the tailored deposition conditions discussed herein. For example, the first molecular species may be available to bond with a reactive surface species on the substrate, or that otherwise couples with a surface of the photoresist material. In embodiments, the first molecular species may have the formula:

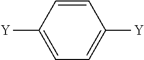

where “—Y” represents a reactive group that can form a covalent bond with the substrate surface under accommodating reaction conditions. In embodiments, unreacted first molecular species in the first deposition precursor effluent may be removed from the substrate surface to prepare for the formation of additional compound layers or a treatment of the compound layer to form the carbon-containing material on the substrate.

The second molecular species may be represented by the formula:

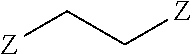

where “—Z” represents a reactive group that can form a covalent bond with an unreacted “—Y” on the layer formed by the reaction of the first deposition precursor with the substrate surface. In embodiments, unreacted second molecular species in the second deposition precursor effluent may be removed from the substrate surface to prepare for the formation of additional compound layers or a treatment of the compound layer to form the carbon-containing material on the substrate.

In embodiment, the first deposition precursor may include two reactive groups “—Y” arranged in the para position around a central aromatic ring. Exemplary —Y groups may include a hydroxide group, an aldehyde group, a ketone group, an acid group, an amino group, an isocyanate group, a thiocyanate group, or an acyl chloride group, among other reactive groups. In additional embodiments, there may be two or more —Y groups, three or more —Y groups, four or more —Y groups, five or more —Y groups that arranged around the aromatic ring. Additional embodiments also include each —Y group being the same reactive group, at least two —Y groups being different reactive groups, and all —Y groups being different reactive groups, among other combinations of —Y groups in the first deposition precursor. Specific examples of first deposition precursors include hydroquinone, terephthalaldehyde, terephthaloyl chloride, and p-phenylenediamine, among others.

In embodiments, the second deposition precursor includes two reactive groups “—Z” arranged on opposite carbons of an ethyl group. The reactive “—Z” groups are selected to be reactive with “—Y” groups under the processing conditions proximate to the substrate surface where the first portion of the compound layer was formed. Exemplary —Z groups may include a hydroxide group, an aldehyde group, a ketone group, an acid group, an amino group, an isocyanate group, a thiocyanate group, or an acyl chloride group, among other reactive groups. Specific examples of second deposition precursors include ethylene glycol, and ethylene diamine, among others.

The —Y groups and —Z groups may be selected to form a covalent reaction bond when the groups come into contact near the substrate surface. Exemplary combinations of —Y groups and —Z groups in the first and second deposition precursors may include acyl chloride —Y groups and hydroxyl —Z groups, and aldehyde —Y groups and amino —Z groups, among other combinations of —Y groups and —Z groups. Specific combinations of first and second deposition precursors may include terephthaloyl chloride and ethylene glycol, terephthalaldehyde and ethylene diamine, and p-phenylenediamine and succinaldehyde, among other combinations.

In still further embodiments, the first deposition precursor may include a central linking group other than a phenyl group, and the second deposition precursor may include a central linking group other than an ethylene group. For example, the first and second deposition precursors may be represented by:

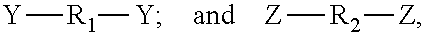

where the —Y groups may be as described above and the —R₁— and —R₂— groups may independently represent an alkyl group, an aromatic group, or a cycloalkyl group, among other types of hydrocarbon groups.

Due at least in part to the processing conditions selected, and the selectivity of the material, the first molecular species may selectively couple with one or more exposed sidewalls 420a and top surface 420b of photoresist material 420, in one or more first deposition cycles, as illustrated in FIG. 4B. While FIG. 4B illustrates that little to no excess re-shaping material 425a is formed over the top surface 420b of the photoresist material 420, it should be understood that, in embodiments, re-shaping material 425 may be formed over the sidewalls 420a and top surface 420b simultaneously or sequentially. For instance, in embodiments, a re-shaping material 425 may first deposit over a top surface 420b followed by deposition over one or more sidewalls 420a. However, in embodiments, the present technology has found that it may be beneficial to first deposit the re-shaping material selectively over one on or more sidewalls 420a with little to no deposition on top surface 420b of photoresist material 420, decreasing the critical dimension between adjacent features (e.g. increasing the aspect ratio of apertures 435). Thus, as illustrated, in embodiments, one or more first deposition cycles may be selective to deposition on sidewalls 420a with little to no deposition over top surface 420b. However, in embodiments, formation of the first carbon-containing layer 425a, 425b may be a generally conformal process, and may deposit a re-shaping material 425 somewhat consistently over both the sidewalls 420a and top surface 420b

In embodiments, it may be desired to further increase the height of the features (e.g. in a non-conformal manner) by further deposition on one or more top surfaces 420b. In such a manner, sidewall deposition may occur prior to further increasing the aspect ratio (such as by non-conformal deposition on one or more top surfaces 420b), allowing for greater control and accuracy over the sidewall deposition. Furthermore, by using a bifurcated deposition process, the present technology has found that tailored thicknesses may be selected for sidewall deposition and top surface deposition, allowing for even greater control over the re-shaping of the photoresist material 420, and further, that other processes, such as chemical vapor deposition, may be utilized to form one or more second layers of re-shaping material, such as helmet or cap 425c over the selectively deposited material 425a, 425b, such as on one or more top surfaces 420b.

Nonetheless, depending on the thickness desired, the deposition cycle of the first molecular species and second molecular species, such as during the selective deposition, including selective sidewall deposition, may be repeated greater than or about 2 times, and may be repeated greater than or about 5 times, greater than or about 10 times, greater than or about 25 times, greater than or about 50 times, greater than or about 100 times, or more. This may produce a carbon-containing layer selectively over the photoresist material 420. Unlike self-assembled monolayers, which may be produced only to a few dozen Angstrom or less, or atomic layer deposition processes which may fail to provide controlled layer-by-layer growth, the carbon-containing material of embodiments of the present technology may be formed to a thickness of greater than or about 0.1 nm, greater than or about 0.2 nm, greater than or about 0.3 nm, greater than or about 0.4 nm, greater than or about 0.5 nm, greater than or about 0.6 nm, greater than or about 0.7 nm, greater than or about 0.8 nm, greater than or about 0.9 nm, greater than or about 1 nm, greater than or about 1.2 nm, greater than or about 1.4 nm, greater than or about 1.6 nm, greater than or about 1.8 nm, greater than or about 2 nm, greater than or about 3 nm, greater than or about 4 nm, greater than or about 5 nm, greater than or about 10 nm, greater than or about 15 nm, greater than or about 20 nm, greater than or about 50 nm, greater than or about 75 nm, greater than or about 100 nm, or more. However, as discussed above, in embodiments, it is desired to carefully control the layer thickness, and may therefore form layer thicknesses, such as selectively over the sidewalls alone or in combination with a top surface, of less than or about 50 nm, less than or about 25 nm, less than or about 20 nm, less than or about 15 nm, less than or about 10 nm, less than or about 9 nm, less than or about 8 nm, less than or about 8 nm, less than or about 7 nm, less than or about 6 nm, less than or about 5 nm, less than or about 4 nm, less than or about 3 nm, less than or about 2 nm, or any ranges or values therebetween.

For instance, in embodiments, it may be desired to carefully control the critical dimension CD between adjacent features. Thus, in embodiments, a selective sidewall re-shaping material 425a may first be deposited at a thickness, reducing the critical dimension to a second critical dimension CD2, as illustrated from FIGS. 4A to 4B. However, as illustrated and discussed above, it should be clear that selective sidewall re-shaping may include some deposition over top surface 420b at a thickness that is at or less than the sidewall re-shaping material thickness, but may not exceed the thickness of the sidewall re-shaping material during the one or more first deposition cycles. Thus, in embodiments, the sidewall re-shaping material may be formed according to the method discussed above, and utilize a number of cycles, forming a sidewall re-shaping material 425a alone or in combination with a top surface material 425b having a thickness of less than or about 10 nm, less than or about 9 nm, less than or about 8 nm, less than or about 8 nm, less than or about 7 nm, less than or about 6 nm, less than or about 5 nm, less than or about 4 nm, less than or about 3 nm, less than or about 2 nm, or such as greater than or about 0.1 nm, greater than or about 0.2 nm, greater than or about 0.3 nm, greater than or about 0.4 nm, greater than or about 0.5 nm, greater than or about 0.6 nm, greater than or about 0.7 nm, greater than or about 0.8 nm, greater than or about 0.9 nm, greater than or about 1 nm, greater than or about 1.2 nm, greater than or about 1.4 nm, greater than or about 1.6 nm, greater than or about 1.8 nm, greater than or about 2 nm, or any ranges or values therebetween. In embodiments, the sidewall re-shaping material 425a alone or in combination with top surface material 425b may be deposited at a thickness of less than or about 5 nm, less than or about 4 nm, less than or about 3 nm, less than or about 2 nm, or such as greater than or about 0.1 nm, greater than or about 0.2 nm, greater than or about 0.3 nm, greater than or about 0.4 nm, greater than or about 0.5 nm, greater than or about 0.6 nm, greater than or about 0.7 nm, greater than or about 0.8 nm, greater than or about 0.9 nm, greater than or about 1 nm, greater than or about 1.2 nm, greater than or about 1.4 nm, greater than or about 1.6 nm, greater than or about 1.8 nm, greater than or about 2 nm, or any ranges or values therebetween.

In embodiments, the deposition temperature of the materials may impact the selectivity of the deposition between exposed photoresist materials and exposed dielectric materials. The present technology has found that low temperature deposition provides good selectivity with the present materials, and also makes the process well suited for use with photoresist materials, as photoresist materials are sensitive to high temperatures. Accordingly, in embodiments, forming the carbon-containing materials during the one or more first cycles may be performed at a substrate temperature and/or chamber temperature of less than or about 150° C., such as less than or about 140° C., less than or about 130° C., less than or about 120° C., less than or about 110° C., less than or about 100° C., less than or about 90° C., less than or about 80° C., less than or about 70° C., less than or about 60° C., or any ranges or values therebetween. Thus, the present technology may be well suited for depositing over photoresist materials, as the process temperature can be selected to be a temperature below a degradation temperature of the photoresist material.

The formation rate of the re-shaping material may also depend on the pressure of the first deposition precursor effluent in the substrate processing region. Exemplary effluent pressures in the substrate processing region may range from about 1 m Torr to about 500 Torr. Additional exemplary ranges include about 1 Torr to about 20 Torr, about 5 Torr to about 15 Torr, and about 9 Torr to about 12 Torr, among other exemplary ranges, as well as any ranges or values therebetween.

The first deposition precursor effluent (e.g. containing the first molecular deposition species) may remain in the substrate processing region for a period of time to nearly or completely form the first layer of the re-shaping material. The precursors may then be delivered in alternating pulses to grow the material layers. In some embodiments, the pulse times of either or both of the first deposition precursor and the second deposition precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more. In some embodiments the first deposition precursor may be pulsed for longer periods of time than the second deposition precursor. In embodiments, by increasing the residence time of the first deposition precursor, improved adhesion may be produced across the photoresist material. The second deposition precursor may then more readily react with the ligands of the first deposition precursor, and thus the second deposition precursor may be pulsed for less time, which may improve throughput. For example, in some embodiments, the second precursor may be pulsed for less than or about 90% of the time the first precursor is pulsed. The second precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

In embodiments, it may be desired to purge or remove the first deposition precursor effluents from the substrate processing region following the formation of the first portion of the re-shaping material. The effluents may be removed by pumping them out of the substrate processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the substrate processing region to assist in the removal of the effluents. Exemplary purge gases include helium and nitrogen, among other purge gases.

After the removal of the first deposition precursor effluents, a second deposition precursor (e.g. effluents of the second molecular species) may flow into the substrate processing region. The second precursor may be a carbon-containing precursor that has at least two reactive groups that can form bonds with unreacted reactive groups of the first deposition precursor, as discussed above. Molecules of the second precursor react with the unreacted reactive groups of the first deposition precursor to form bonds linking the second precursor molecules to the first precursor molecules. The reactions between the second and first precursor molecules continue until most or all the unreacted reactive groups on the first precursor molecules have reacted with second precursor molecules.

The formation rate of the second portion of the compound layer may also depend on the pressure of the second deposition precursor effluent in the substrate processing region. Exemplary effluent pressures in the substrate processing region may range from about 1 Torr to about 20 Torr. Additional exemplary ranges include about 5 Torr to about 15 Torr, and about 9 Torr to about 12 Torr, among other exemplary ranges, such as any one or more pressures discussed above, or any ranges or values therebetween.

In embodiments, it may also be desirable to purge or remove the second deposition precursor effluents from the substrate processing region following the formation of the second portion of the compound layer. The effluents may be removed by pumping them out of the substrate deposition region for a period of time ranging from about 10 seconds to about 100 seconds. Additional exemplary time ranges may include about 20 seconds to about 50 seconds, and 25 seconds to about 45 seconds, among other exemplary time ranges. In some embodiments, a purge gas may be introduced to the substrate processing region to assist in the removal of the effluents. Exemplary purge gases include helium and nitrogen, among other purge gases.

Nonetheless, in embodiments, it may be desired to increase a height of one or more of the features, as illustrated in FIG. 4C, at optional operation 320. As illustrated, in embodiments, it may be desirable to increase a height h, of the photoresist material to a second height h2. As discussed above, in embodiments, it may be desirable to increase the height after formation of the selective layer of re-shaping material over the one or more sidewalls 425a alone or in combination with top surface 425b, as increasing the height may further increase the aspect ratio, increasing the difficulty in controlled deposition over the sidewalls 420a. However, as previously set forth, in embodiments, the height may be increased prior to deposition over one or more sidewalls 420a.

Nonetheless, in embodiments, the present technology has found that the height may be increased by depositing a carbon-containing helmet or cap material 425c over a top surface 420b of the feature, such as directly over a portion of re-shaping material 425b present over top surface 420b. In embodiments, the carbon-containing material may be any one or more of the materials discussed above, and may utilize a first molecular species and second molecular species according to the above discussed molecular deposition process. However, in embodiments, as the selective deposition has already taken place, it may also be possible to utilize chemical vapor deposition, in embodiments, to selectively deposit the carbon containing material over the top surface 420b and/or re-shaping material 425b.

In embodiments, if a molecular layer deposition process is utilized, it may be desired to alter one or more processing conditions in order to selectively deposit over a top surface 420b and/or re-shaping material 425b. For instance, in embodiments, it may be desirable to utilize one or more of high pressure, low plasma power, low precursor density, or a combination thereof. However, in embodiments, it may not be necessary to alter one or more of the processing conditions, as the increased aspect ratio may facilitate formation predominantly on the top surface.

For instance, in embodiments, local plasma formed of the one or more deposition precursors may provide directional flow of plasma effluents to the structure 400 to provide a top heavy deposition, such as at operation 320. The plasma may be a low-density plasma to limit the amount of bombardment, sputtering, and surface modification. In embodiments, a capacitively-coupled plasma may be formed within the processing region by applying source plasma power above the substrate 405 or to substrate support, such as the substrate support pedestal previously described, as previously described. The source plasma power may be less than or about 1,000 W, less than or about 900 W, less than or about 800 W, less than or about 700 W, less than or about 600 W, less than or about 500 W, less than or about 400 W, less than or about 300 W, or less. The plasma power may also be between any of these stated plasma powers, or within smaller ranges encompassed by any of these numbers. By utilizing a plasma power that is, for example, about 1,000 W or less, 750 W or less, or even 500 W or less, the plasma effluents may be better controlled to deposit a helmet or cap material 425c, such as a top surface heavy carbon-containing material, selectively on the photoresist material 420 at operation 320.

The pressure within the processing chamber may be controlled during method 300. For example, the pressure within the processing chamber may be maintained below or about 30 Torr. Additionally, in embodiments, the pressure within the processing chamber may be maintained below or about 28 Torr, below or about 26 Torr, below or about 24 Torr, below or about 22 Torr, below or about 20 Torr, below or about 18 Torr, below or about 16 Torr, below or about 14 Torr, below or about 12 Torr, below or about 10 Torr, below or about 8 Torr, below or about 6 Torr, or lower, although the pressure may also be included in ranges between any two of these stated numbers or within any smaller range encompassed by any of the stated ranges. In embodiments, the pressure may additionally be maintained at greater than or about 4 Torr, greater than or about 6 Torr, greater than or about 8 Torr, greater than or about 10 Torr, greater than or about 12 Torr, greater than or about 14 Torr, greater than or about 16 Torr, greater than or about 18 Torr, greater than or about 20 Torr, greater than or about 22 Torr, greater than or about 24 Torr, greater than or about 26 Torr, greater than or about 28 Torr, or higher. Pressure may affect deposition of the material 430, and at higher pressures, as discussed above, a more conformal deposition may result. While the deposition at operation 315 may be mainly by temperature, due at least in part to the thermal MLD process, higher pressures during operation 320 may result in a plasma process preferring a top heavy deposition, and may at least partially if not fully selectively form a helmet or cap over top surface 420b.

During operation 320, a duty cycle of the source power may be less than or about 75%, and the source power may be operated at a duty cycle of less than or about 70%, less than or about 60%, less than or about 50%, less than or about 40%, less than or about 30%, less than or about 20%, or less. By operating the source power for a reduced duty cycle, such as an on-time duty of less than or about 50%, the material 430 deposited on the photoresist material may deposit preferentially on the top surface of the photoresist material 420b.

Nonetheless, in embodiments, the helmet or cap material 425c may have any one or more of the above discussed thicknesses. However, in embodiments, the helmet or cap 425c may be deposited at a thickness of greater than or about 1 nm, greater than or about 2 nm, greater than or about 3 nm, greater than or about 4 nm, greater than or about 5 nm, greater than or about 6 nm, greater than or about 7 nm, greater than or about 8 nm, greater than or about 9 nm, greater than or about 10 nm, or less than or about 50 nm, less than or about 25 nm, less than or about 20 nm, less than or about 15 nm, less than or about 10 nm, less than or about 9 nm, less than or about 8 nm, less than or about 8 nm, less than or about 7 nm, less than or about 6 nm, less than or about 5 nm, or any ranges or values therebetween. For instance, in embodiments, the helmet or cap 425c may allow for etching to a greater depth with apertures 435 without depletion of the photoresist material.

In some embodiments the re-shaping material may be fully selective such that the carbon-containing material forms only over the photoresist material, and little or no carbon-containing material may form on the exposed portions of the dielectric material. In some embodiments, an amount of coverage may occur overlying the dielectric material, although the amount may be reduced relative to the thickness formed overlying the photoresist material. For example, an amount formed on the dielectric material may be characterized by a thickness that is less than or about 90% of a thickness formed over the photoresist material, and the amount formed on the dielectric material may be characterized by a thickness that is less than or about 80% of a thickness formed over the photoresist material, less than or about 70% of the thickness formed over the photoresist material, less than or about 60% of the thickness formed over the photoresist material, less than or about 50% of the thickness formed over the photoresist material, less than or about 40% of the thickness formed over the photoresist material, less than or about 30% of the thickness formed over the photoresist material, less than or about 20% of the thickness formed over the photoresist material, less than or about 10% of the thickness formed over the photoresist material, less than or about 5% of the thickness formed over the photoresist material, less than or about 1% of the thickness formed over the photoresist material, or less, in some embodiments.

If material is formed over the dielectric material on which subsequent deposition or etch may be performed, a subsequent process may be performed to re-expose the underlying dielectric material. For example, an oxidant may be delivered to the processing region to react with the carbon-containing material and etch an amount sufficient to expose the dielectric surface. The oxidation may be plasma enhanced, such as by providing an oxygen-containing precursor and forming a plasma to produce oxygen radical species, which may etch the carbon-containing material. Additionally, ozone or some other reactive material to remove carbon-containing material may be used, and which may not be plasma enhanced to limit additional damage to the blocking structure. Although the etch may additionally etch carbon-containing material, the one or more layers of re-shaping material may still provide excellent correction of the as-deposited photoresist material.

Nonetheless, after re-shaping of the photoresist material 420 with re-shaping material 425, the semiconductor structure 400 may be etched at optional operation 325, as illustrated in FIG. 4D. Namely, as illustrated, some or all of the dielectric material 410 located in zones 415 (e.g. within apertures 435) may be etched, as defined by the re-shaped photo resist pattern. The re-shaped photo resist pattern is shown intact, however, it should be understood that, in embodiments, a non-selective etch material may be utilized, such as one or more plasma processes including one or more reactive plasma precursors (e.g. fluorine, in embodiments), and some or all of the re-shaped photoresist material may be consumed during etching. Nonetheless, due to the re-shaping, a high degree of conformance to the desired etch pattern can be achieved.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a selective layer of carbon-containing material on a photoresist material disposed over a surface of a substrate, wherein the selective layer of carbon-containing material is selectively formed over at least one or more sidewalls of the photoresist material, and wherein forming the selective layer of carbon-containing material comprises one or more cycles of:
providing a first molecular species that selectively couples with the photoresist material, and
providing a second molecular species that selectively couples with the first molecular species.

2. The semiconductor processing method of claim 1, wherein the selective layer of carbon-containing material is formed over the one or more sidewalls and one or more top surfaces of the photoresist material.

3. The semiconductor processing method of claim 2, further comprising forming a helmet or cap over the selective layer of carbon-containing material on the one or more top surfaces of the photoresist material.

4. The semiconductor processing method of claim 3, wherein the helmet or cap comprises a carbon-containing material.

5. The semiconductor processing method of claim 4, wherein the helmet or cap is formed by molecular layer deposition, chemical vapor deposition, or a combination thereof.

6. The semiconductor processing method of claim 1, wherein the selective layer of carbon-containing material is deposited by molecular layer deposition.

7. The semiconductor processing method of claim 6, wherein the selective layer of carbon-containing material is deposited at a thickness of less than or about 5 nm.

8. The semiconductor processing method of claim 7, wherein the selective layer of carbon-containing material is deposited at a thickness of less than or about 4 nm over the one or more sidewalls and the one or more top surfaces of the photoresist material.

9. The semiconductor processing method of claim 3, wherein the helmet or cap is formed at a thickness of greater than or about 5 nm.

10. The semiconductor processing method of claim 9, wherein the helmet or cap increases a height of the photoresist material.

11. The semiconductor processing method of claim 2, wherein the selective layer of carbon-containing material decreases a critical dimension between adjacent features of the photoresist material.

12. The semiconductor processing method of claim 1, wherein the selective layer of carbon-containing material is formed at a temperature of less than or about 150° C.

13. A semiconductor processing method comprising:
flowing a first deposition precursor into a substrate processing region, contacting a photoresist material formed over a surface of a substrate within the substrate processing region of a semiconductor processing chamber, selective forming a first portion of a carbon-containing material,
flowing a second deposition precursor into the substrate processing region, contacting the first portion of the carbon-containing material, forming a second portion of the carbon-containing material;
wherein the carbon-containing material is selectively formed over the photoresist material.

14. The semiconductor processing method of claim 11, wherein the carbon-containing material is selective formed over one or more sidewalls and one or more top surfaces of the photoresist material.

15. The semiconductor processing method of claim 14, further comprising forming a helmet or cap over the selective carbon-containing material on the one or more top surfaces of the photoresist material.

16. The semiconductor processing method of claim 15, wherein the helmet or cap comprises a carbon-containing material, and wherein the helmet or cap is formed by molecular layer deposition, chemical vapor deposition, or a combination thereof, selectively over the selective carbon-containing material on the one or more top surfaces of the photoresist material.

17. The semiconductor processing method of claim 15, wherein the selective carbon-containing material is deposited at a thickness of less than or about 4 nm over the one or more sidewalls and wherein a thickness over the one or more top surfaces is less than a thickness over the one or more sidewalls.

18. A semiconductor processing method comprising:
forming a selective layer of carbon-containing material on a photoresist material disposed over a dielectric material formed on a surface of a substrate within a processing region of a semiconductor processing chamber at a processing region temperature of less than or about 100° C., wherein the selective layer of carbon-containing material is selectively formed over the photoresist material, and wherein forming the selective layer of carbon-containing material comprises one or more cycles of:
providing a first molecular species that selectively couples with photoresist material; and
providing a second molecular species that selectively couples with the first molecular species.

19. The semiconductor processing method of claim 18, further comprising:
forming a helmet or cap over the selective layer of carbon-containing material on one or more top surfaces of the photoresist material.

20. The semiconductor processing method of claim 19, further comprising etching an exposed portion of the dielectric material after forming the selective layer of carbon-containing material.
